(19) United States
(12) Patent Application Publication
(10) Pub. No.: US 2018/0056479 A1
(43) Pub. Date: Mar. 1, 2018

(54) CHEMICAL MECHANICAL POLISHING TOOL WITH ROBOT ACCESS TO CASSETTES

(71) Applicant: Applied Materials, Inc., Santa Clara, CA (US)

(72) Inventors: Yongqi Hu, Fremont, CA (US); Thomas Lawrence Terry, Hollister, CA (US)

(21) Appl. No.: 15/686,667

(22) Filed: Aug. 25, 2017

Related U.S. Application Data
(60) Provisional application No. 62/380,273, filed on Aug. 26, 2016.
(60) Provisional application No. 62/464,204, filed on Feb. 27, 2017.

(51) Int. Cl. B24B 37/34; H01L 21/677; H01L 21/687; H01L 21/67; G05B 19/19

(52) U.S. Cl. CPC B24B 37/345; H01L 21/67766; H01L 21/67769; H01L 21/67772; H01L 21/30625; H01L 21/68707; H01L 21/67075; H01L 21/67092; G05B 19/19; H01L 21/67778

(57) ABSTRACT

A semiconductor fabrication system includes a chemical mechanical polishing system, a cassette holding area enclosed by a wall and having a door openable by an operator to place one or more cassettes into the cassette holding area, a robot configured to transfer substrates between a cassette in the cassette holding area to the chemical mechanical polishing system, a computer controller configured to cause the robot to move to a home position, a circuit breaker in a power supply line to the robot, a door sensor to detect whether the door is open, a robot presence sensor to detect whether the robot is in the home position, and control circuitry configured to receive signals from the door sensor and the robot presence sensor and cause the circuit breaker to cut power to the robot if the door is open and the robot is not in the home position.

### CROSS-REFERENCE TO RELATED APPLICATIONS

This application claims priority to U.S. Application Ser. No. 62/380,273, filed on Aug. 26, 2016, and claims priority to U.S. Application Ser. No. 62/464,204, filed Feb. 27, 2017, the entire disclosures of which are incorporated by reference.

### TECHNICAL FIELD

The present disclosure relates to chemical mechanical polishing, and in particular to controlling a robot that accesses cassettes in a chemical mechanical polishing tool.

### BACKGROUND

An integrated circuit is typically formed on a substrate by the sequential deposition of conductive, semiconductive, or insulative layers on a silicon wafer. A variety of fabrication processes require planarization of a layer on the substrate. For example, one fabrication step involves depositing a conductive filler layer on a patterned insulative layer to fill the trenches or holes in the insulative layer. The filler layer is then polished until the raised pattern of the insulative layer is exposed. After planarization, the portions of the conductive filler layer remaining between the raised pattern of the insulative layer form vias, plugs and lines that provide conductive paths between thin film circuits on the substrate. Another fabrication step involves planarization of an insulative layer until it reaches a target thickness over an underlying layer.

Chemical mechanical polishing (CMP) is one accepted method of planarization. A chemical mechanical polishing system typically includes a carrier head to hold the substrate against a rotating polishing pad. The carrier head provides a controllable load on the substrate to push it against the polishing pad. A polishing liquid, such as slurry with abrasive particles, is supplied to the surface of the polishing pad.

To transfer the substrates to the chemical mechanical polishing system, the substrates are typically loaded into a cassette, e.g., manually or at a previous processing station. This cassette can then be carried and placed into a factory interface module, which is typically an area accessible to the cleanroom environment of the semiconductor manufacturing facility. A robot can transfer a substrate from a cassette in the factory interface module to a load/unload station in the CMP tool, where the substrate can be loaded into or unloaded from the carrier head.

### SUMMARY

In one aspect, a semiconductor fabrication system includes a chemical mechanical polishing system, a cassette holding area enclosed by a wall and having a door openable by an operator to place one or more cassettes into the cassette holding area, a robot configured to transfer substrates between a cassette in the cassette holding area to the chemical mechanical polishing system, a computer controller configured to cause the robot to move to a home position, a circuit breaker in a power supply line to the robot, a door sensor to detect whether the door is open, a robot presence sensor to detect whether the robot is in the home position, and control circuitry configured to receive signals from the door sensor and the robot presence sensor and cause the circuit breaker to cut power to the robot if the door is open and the robot is not in the home position.

In another aspect, a method of operating a semiconductor fabrication system includes transferring substrates from a cassette loading area to a chemical mechanical polishing system with a robot, opening a door to the cassette loading area and loading a cassette having substrates into the cassette holding area, detecting whether the door is open, detecting whether the robot is in a home position, and in response to detecting that the door is open and that the robot is not in the home position, cutting power to the robot.

Certain implementations can include one or more of the following advantages. The robot can be prevented from moving away from a home position when a door to the factory interface module is open. Safety of the human operator can be maintained, while the downtime of the system can be reduced.

The details of one or more implementations are set forth in the accompanying drawings and the description below. Other aspects, features and advantages will be apparent from the description and drawings, and from the claims.

### BRIEF DESCRIPTION OF DRAWINGS

FIG. 1 is a schematic perspective view of a processing system that includes a chemical mechanical polishing system.

FIG. 2 is schematic top view of a processing system that includes a chemical mechanical polishing system.

FIG. 3 is a schematic side view of a robot in a home position.

FIG. 4 is a schematic block diagram of a robot interlock.

FIG. 5 is a flow chart illustrating operation of the robot interlock.

Like reference symbols in the various drawings indicate like elements.

### DETAILED DESCRIPTION

In order to protect the operator, it is important that the robot be immobilized when cassettes are to be loaded or unloaded in a chemical mechanical polishing system. One technique to accomplish this is to have a switch on the doors, with the switch connected to the robot's contactors (effectively a circuit breaker for the robot) such that power is cut to the robot when the door is opened. Completely cutting power to the robot may be required by various state or national occupational safety regulations. Unfortunately, once power is cut to the robot, restarting the robot after the doors are closed can require complete re-initialization of the robot, which can be time-consuming (e.g., more than 80 seconds), reducing throughput.

By placing a sensor system in the cassette holding area that will trigger the robot contactors when the robot moves from a home position, operator safety can be maintained while permitting the doors to be opened without requiring re-initialization of the robot.

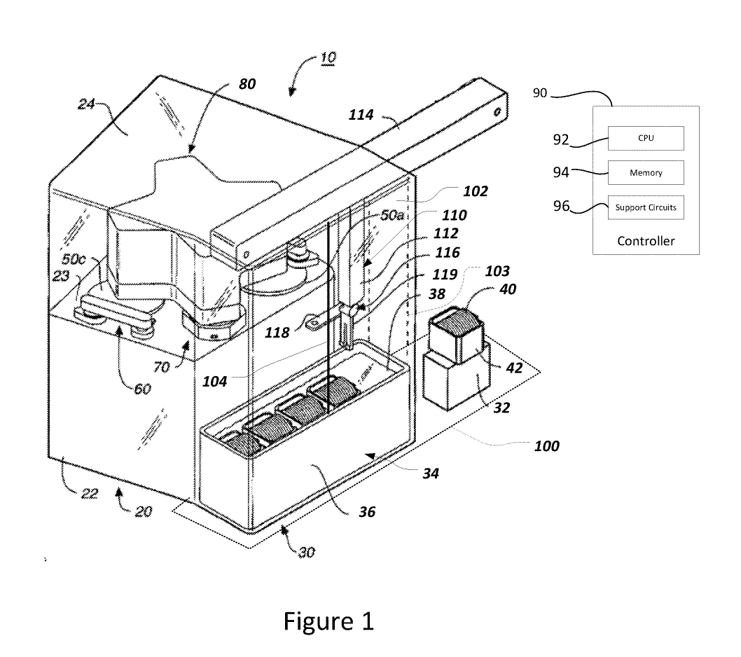

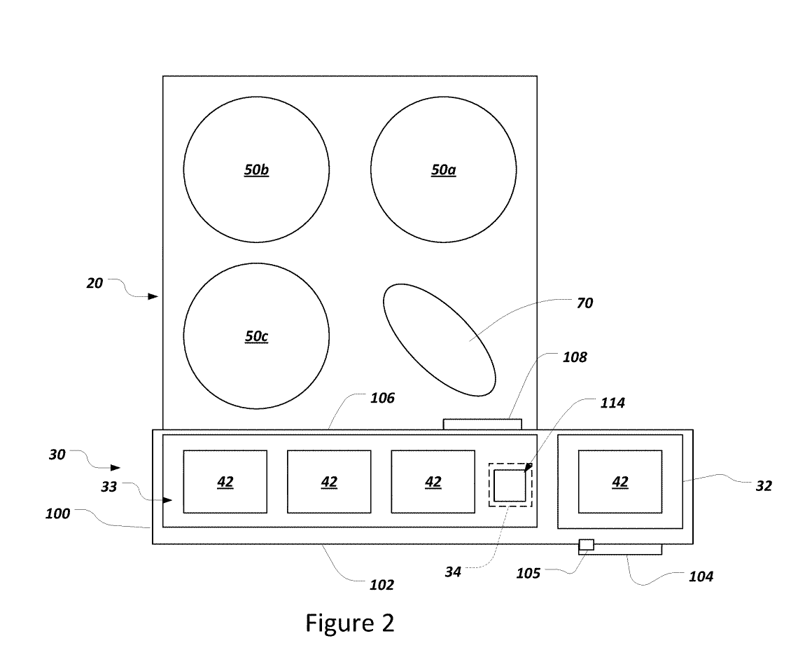

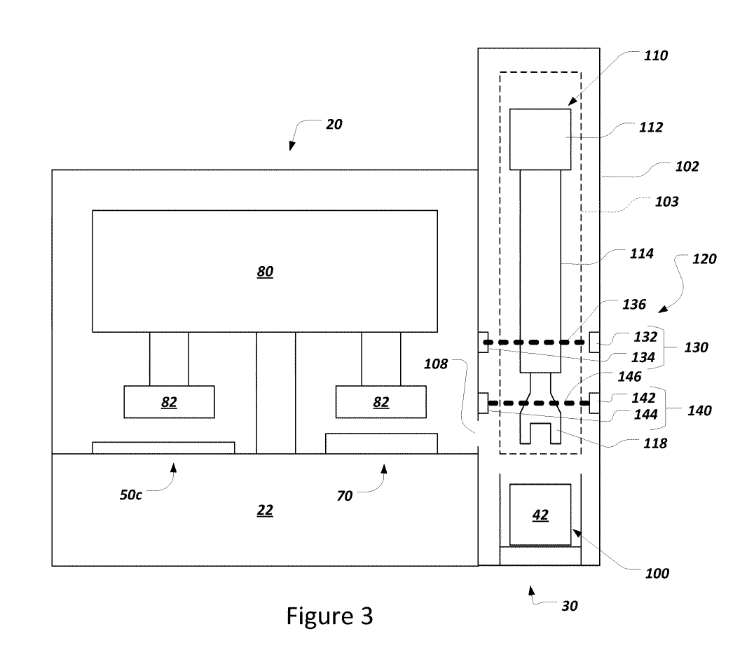

Referring to FIG. 1, a substrate processing system 10 includes a chemical mechanical polishing system 20 located adjacent to a substrate loading apparatus 30. The substrate loading apparatus 30 includes a cassette holding area 100 enclosed by a wall 102, which can be transparent. A door 104 is located in the wall 102 to permit access by the operator of the facility to a cassette holding area 100 (see FIG. 1), which can include a cassette loading area 32 and/or a cassette staging area 33 (see FIG. 2). The wall 102 can enclose the cassette loading area 32 (see FIG. 2). An aperture 103 (see FIGS. 1 and 3) can provide access between the cassette loading area 32 and the cassette staging area 33.

The substrate loading apparatus 30 also includes a robot 110, e.g., a wet robot, to transfer substrates between cassettes in the holding area 100, e.g., in the cassette staging area 33, to the chemical mechanical polishing system 20. The robot 110 can also be used to transfer cassettes between the loading area 32 and the staging area 33.

Substrates 40 are transported to the substrate processing system 10 in one or more cassettes 42. An operator opens the door 104, places the cassette 42 in the loading area 32, e.g., on support, and then closes the door 104. The robot 110 then transfers the cassette 42 from the loading area 32 to the staging area 33. Alternatively, if the door 104 leads directly to the staging area 33, then the operator can place the cassette 42 directly into the staging area 33.

One or more substrates 40 are then extracted from the cassette 42 in the staging area 33 and loaded into the chemical mechanical polishing system 20 by the robot 110. The polishing system 20 then polishes the substrates 40, and the robot 110 then returns the substrates 40 to either the original cassette 42 or a different cassette in the staging area 33. Once the desired polishing operations are completed for substrates in the cassette 42, the robot can transfer the cassette 42 back to the loading area 32, and the operator can open the door 104 and remove the cassette 42 and then close the door (or for some positions of the door, the operator could remove the cassette directly from the staging area 33).

The operations of the substrate processing system 10, such as motion of the robot 110, can be coordinated by controller 90, which may include one or more programmable digital computers executing control software. For example, the controller 90 can include a CPU 92, memory 94 to store the software, and other support circuits 96, e.g., input/output devices, storage devices, etc.

The chemical mechanical polishing system 20 can be a Mirra® chemical mechanical polisher manufactured by Applied Materials, Inc. of Santa Clara, Calif. A description of a polisher may be found in U.S. Pat. No. 5,738,574.

The polishing system 20 can include a lower machine base 22 with a table top 23 mounted thereon and a removable upper outer cover 24. The machine base can support a series of polishing stations (two stations 50a and 50c are visible) and a transfer station 70. The polishing system 20 can also include one or more carrier heads 82 (see FIG. 3) suspended from a carrier head transport mechanism 80, such as a rotatable carousel. Each polishing station includes a rotatable platen on which is placed a polishing pad, and an associated pad conditioner apparatus 60 to maintain the polishing pad in an abraded condition.

The transfer station 70 serves multiple functions of receiving individual substrates 40 from the loading apparatus 30 via the robot 110, loading the substrate 40 to the carrier heads, receiving the substrates 40 back from the carrier heads, and finally transferring the substrates back to the robot 110 to be carried back to the loading apparatus 30. The transfer station 70 can also possibly rinse or wash the substrates, before and/or after the polishing operation.

A wall 106 (see FIG. 2) can be interposed between the polishing apparatus 20 and the wafer loading apparatus 30 so as to contain slurry and other polishing debris within the polishing apparatus 20 and away from the cassette holding area 100. A port 108 (see FIG. 2), such as an opening or sliding door, can be located in the wall 106 for the transfer of substrates by the robot 110 between the polishing system 20 and the loading apparatus 30. The wall 106 may act as the barrier between the clean room containing the wafer loading apparatus 30 and a dirtier area containing the polishing apparatus 20.

In some implementations, the cassette staging area 33 includes a holding tub 36 filled with a liquid bath 38, such as deionized water, to receive the cassettes 42. The bath can be sufficiently deep that the cassettes 42 and the wafers 40 contained therein are submersed. Alternatively, the cassettes 42 can simply be placed on a support, such as stand or shelf, or on the floor, in the cassette staging area 33.

The robot 110 can include an extensible arm 112 descending pending from an overhead track 114. The lower end of the arm 112 of the robot 110 can include a wrist assembly 116 including both a wafer blade 118 and/or a cassette claw 119. If the cassette loading area 32 is used, then the cassette claw 119 can be operated to move cassettes 42 between the loading area 32 and the staging area 33. The wafer blade 118 can be operated to move substrates 40 between the cassettes 42 in the cassette staging area 33 and the transfer station 70.

Although FIG. 1 and the remaining figures show the loading area 32 disposed on a side of the machine base 22 away from the transfer station 70, this illustration is merely schematic, and other configurations are possible. In addition, other components, such as a wafer cleaner, a wafer drier, a metrology station, and the like can be integrated into the substrate processing system 10.

Referring to FIG. 2, the controller 90 can be configured to cause the descending arm 112 of the robot 110 to return to a home position 34, e.g., when not otherwise moving substrates between the cassettes 42 and the transfer station 70, or upon command by a user. The home position can be in the cassette staging area 33, e.g., adjacent to the door 108 to the chemical mechanical polishing system 20.

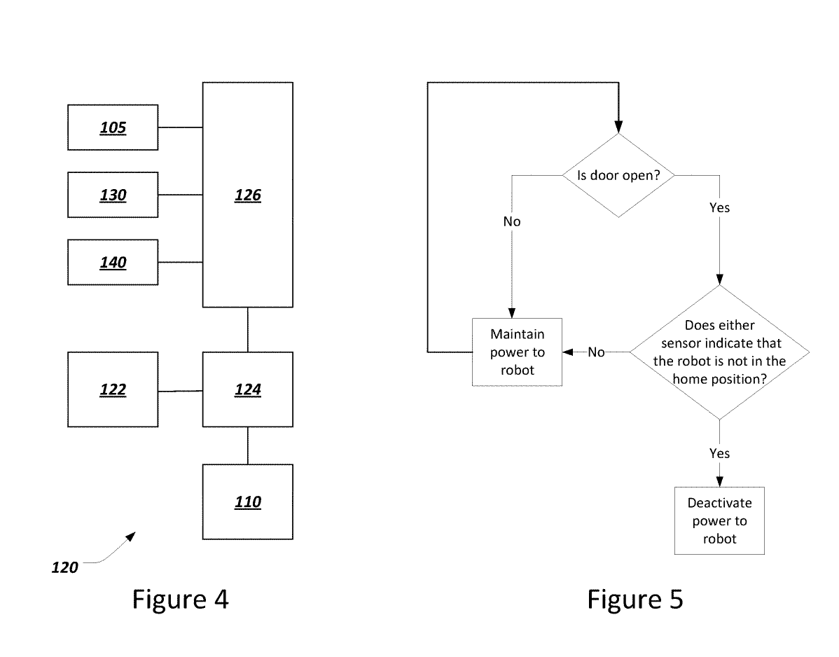

The processing system 10 also includes a robot interlock 120 (see FIG. 4) to prevent the robot 110 from moving while the door 104 to cassette holding area 100 is open, but without cutting power to the robot 110 when the robot is in the holding position 34. This can maintain operator safety while permitting the door 104 to be opened without requiring re-initialization of the robot 110.

Referring to FIG. 4, power for the robot 110 is directed from a power supply 122 through a contactor 124, e.g., a circuit breaker, to the robot. The contactor 124 can be tripped (so that the power to the robot 110 is cut off) by control circuitry 126 that is coupled to several sensors. The contactor 124 can be configured such that once tripped, it needs to be manually “flipped” to restore power to the robot 110.

Referring to FIG. 2, the door 104 includes a switch 105 that generates a signal indicating whether the door 104 is open or closed.

In addition, referring to FIG. 3, the robot interlock 120 includes one or more robot presence sensors to detect whether the robot 110 is in the home position 34. In some implementations, the robot interlock includes a first sensor 130 to detect motion of the arm 112 and a second sensor 140 to detect motion of the robot end effector, i.e., the wafer blade 118 or cassette claw 119.

As an example, the first sensor 130 can include a through-beam sensor that includes a first beam emitter 132, e.g., an LED, and a first detector 134, e.g., a photodetector. The first beam emitter 132 is configured to generate a light beam 136 (which could be visible or non-visible light) that passes through position where the arm 112 is supposed to be located when the robot 110 is in the home position. The first detector 134 is positioned to receive the beam when the beam is not being blocked by the arm 112. Thus, if the first detector 134 detects the light beam 136, this indicates that the arm 112 is not in the holding position.

Similarly, the first sensor 130 can include a through-beam sensor that includes a second beam emitter 142, e.g., an LED, and a second detector 144, e.g., a photodetector. The second beam emitter 142 is configured to generate a light beam 146 (which could be visible or non-visible light) that passes through position where the end effector, e.g., the wafer blade 118, is supposed to be located when the robot 110 is in the home position. The second detector 144 is positioned to receive the beam when the beam is not being blocked by the arm 112, e.g., by the end effector. Thus, if the second detector 144 detects the light beam 146, this indicates that the arm 112, e.g., the end effector, is not in the home position.

Referring to FIG. 5, the control circuitry 126 operates as follows. If the signal from the door sensor 105 indicates that the door 104 is closed, then power to the robot can be maintained, regardless of the signals from the one or more sensors 130, 140. On the other hand, if the signal from the door sensor 105 indicates that the door 104 is open, and either sensor 130, 140 indicates that the robot 110 has moved from the home position 105, then the control circuitry 126 trips the contactor 124, and power is cut from the robot 110. This can require re-initialization of the robot before further operations can be performed. However, if the signal from the door sensor 105 indicates that the door 104 is open, but both sensors 130, 140 indicate that the robot 110 is in the home position, then power to the robot is maintained. This permits the door 104 to be opened so that cassettes 42 can be loaded into the cassette holding area 100, without cutting power to the robot 110, thus avoiding downtime of the robot and increasing throughput of the apparatus while maintaining operator safety. The control circuitry 126, sensors 105, 130 and 140 can all be hardwired, e.g., with analog circuitry, such that the power cut-off cannot be disabled by software.

The control circuitry 126 can include a manual power shut-off switch (e.g., a button) in the event that the operator needs to manually shut off power to the robot. The control circuitry 126 can also include a manually operated power restore switch, e.g., a button, for the operator to “flip” the contactor 124 to restore power to the robot 110, whether after a manual power shut off or an automatic power shut off as described above when the robot is not in the home position and the door is open.

The functional operations of the controller 90 can be implemented through digital electronic circuitry, or in computer software, firmware, or hardware, including the structural means disclosed in this specification and structural equivalents thereof, or in combinations of them.

The functional operations of the controller 90 can be implemented through one or more computer program products, i.e., one or more computer programs tangibly embodied in an information carrier, e.g., in a non-transitory machine-readable storage medium or in a propagated signal, for execution by, or to control the operation of, data processing apparatus, e.g., a programmable processor, a computer, or multiple processors or computers. A computer program (also known as a program, software, software application, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file. A program can be stored in a portion of a file that holds other programs or data, in a single file dedicated to the program in question, or in multiple coordinated files (e.g., files that store one or more modules, sub-programs, or portions of code). A computer program can be deployed to be executed on one computer or on multiple computers at one site or distributed across multiple sites and interconnected by a communication network.

A number of embodiments of the invention have been described. Nevertheless, it will be understood that various modifications may be made without departing from the spirit and scope of the invention. Accordingly, other embodiments are within the scope of the following claims.

What is claimed is:

1. A semiconductor fabrication system, comprising:
a chemical mechanical polishing system;
a cassette holding area enclosed by a wall and having a door openable by an operator to place one or more cassettes into the cassette holding area;
a robot configured to transfer substrates between a cassette in the cassette holding area and the chemical mechanical polishing system;
a computer controller configured to cause the robot to move to a home position;
a circuit breaker in a power supply line to the robot;
a door sensor to detect whether the door is open;
a robot presence sensor to detect whether the robot is in the home position; and
control circuitry configured to receive signals from the door sensor and the robot presence sensor and cause the circuit breaker to cut power to the robot if the door is open and the robot is not in the home position.

2. The system of claim 1, wherein the robot presence sensor comprises a beam emitter configured to direct a light beam through a location where a portion of the robot is supposed to be when the robot is in the home position, and a detector positioned to receive the beam when the beam is not being blocked by the robot.

3. The system of claim 2, wherein the beam emitter is configured to direct the light beam through a location where an arm of the robot is supposed to be when the robot is in the home position.

4. The system of claim 2, wherein the beam emitter is configured to direct the light beam through a location where an end effector of the robot is supposed to be when the robot is in the home position.

5. The system of claim 2, wherein the robot presence sensor comprises a first sensor to detect motion of an arm of the robot and a second sensor to detect motion of an end effector of the robot.

6. The system of claim 5, wherein the first sensor comprises a first beam emitter configured to direct a first light beam through a location where the arm of the robot is supposed to be when the robot is in the home position, and a first detector positioned to receive the first light beam when the beam is not being blocked by the arm, and the second sensor comprises a second beam emitter configured to direct a second light beam through a location where the end effector of the robot is supposed to be when the robot is in the home position, and a second detector positioned to receive the second light beam when the beam is not being blocked by the end effector.

7. The system of claim 1, wherein the cassette holding area comprises a cassette loading area and a cassette staging area, and wherein the robot is configured to transfer the cassette between the loading area and the staging area.

8. The system of claim 7, wherein the home position is in the staging area.

9. The system of claim 8, wherein a wall has aperture connecting the cassette loading area and the cassette staging area, and the home position is adjacent the aperture.

10. The system of claim 7, wherein the door is located in the loading area.

11. The system of claim 7, wherein the robot is configured to remove a substrate from the cassette in the staging area and place the substrate in a transfer station in the chemical mechanical polishing system.

12. The system of claim 11, wherein the robot is configured to retrieve the substrate from the transfer station in the chemical mechanical polishing system and return the substrate to a cassette in the staging area.

13. The system of claim 1, comprising a wall between the cassette holding area and the chemical mechanical polishing system, and a port in the wall for transfer of substrates between the cassette holding area and the chemical mechanical polishing system by the robot.

14. The system of claim 13, wherein the home position is adjacent the port.

15. The system of claim 1, wherein the control circuitry is hardwired.

16. The system of claim 1, wherein the control circuitry comprises a manually operated power restore switch to cause the circuit breaker to restore power to the robot.

17. A method of operating a semiconductor fabrication system, comprising:
transferring substrates from a cassette holding area to a chemical mechanical polishing system with a robot;
opening a door to the cassette holding area and loading a cassette having substrates into the cassette holding area;
detecting whether the door is open;
detecting whether the robot is in a home position; and
in response to detecting that the door is open and that the robot is not in the home position, cutting power to the robot.

18. The method of claim 17, wherein detecting whether the robot is in the home position comprises directing a light beam through a location where a portion of the robot is supposed to be when the robot is in the home position.

19. The method of claim 18, wherein detecting whether the robot is in the home position comprises directing a first light beam through a location where an arm of the robot is supposed to be when the robot is in the home position, and directing a second light beam through a location where an end effector of the robot is supposed to be when the robot is in the home position.

20. The method of claim 17, comprising transferring the cassette from a cassette staging area to a cassette loading area with the robot, and removing a substrate from the cassette in the staging area and placing the substrate in a transfer station in the chemical mechanical polishing system with the robot.
